(19) United States
(12) Patent Application Publication
(10) Pub. No.: US 2022/0068637 A1
(43) Pub. Date: Mar. 3, 2022

(54) FILM-FORMING METHOD, FILM-FORMING APPARATUS, AND OXIDATION METHOD

(71) Applicant: Tokyo Electron Limited, Minato-ku, Tokyo (JP)

(72) Inventors: Kotaro MIYATANI, Nirasaki City, Yamanashi (JP); Naotaka NORO, Boise, ID (US); Kouji SHIMOMURA, Nirasaki City, Yamanashi (JP); Ryoun SHIMAMOTO, Nirasaki City, Yamanashi (JP); Toshiyuki IKEUCHI, Nirasaki City, Yamanashi (JP); Younggi HONG, Hwaseong-si, Gyeonggi-do (KR)

(21) Appl. No.: 17/310,258

(22) PCT Filed: Oct. 28, 2019
(86) PCT No.: PCT/JP2019/042129

§ 371 Date: Jul. 27, 2021

(30) Foreign Application Priority Data
Jan. 29, 2019 (JP) 2019-012693

(51) Int. Cl. H01L 21/02; C23C 16/40; C23C 16/52; C23C 16/44; C23C 16/455

(52) U.S. Cl. CPC H01L 21/02236; H01L 21/02164; C23C 16/45565; C23C 16/52; C23C 16/4408; C23C 16/402

(57) ABSTRACT

A film-forming method of forming an oxide film on a substrate inside a chamber, includes: adsorbing a raw material gas for forming the oxide film onto the substrate by supplying the raw material gas into the chamber; and oxidizing the raw material gas adsorbed onto the substrate with oxygen-containing radicals produced by supplying a hydrogen gas and an oxygen gas into the chamber while preheating the hydrogen gas and the oxygen gas, wherein the adsorbing the raw material gas and the oxidizing the raw material gas are repeated, and when supplying at least one of the hydrogen gas and the oxygen gas, a supply partial pressure of the at least one of the hydrogen gas and the oxygen gas is changed to be relatively high at an initial supply stage and to gradually decrease over time.

### TECHNICAL FIELD

The present disclosure relates to a film-forming method, a film-forming apparatus, and an oxidation method.

### BACKGROUND

In a semiconductor device manufacturing process, there is a step of forming an oxide film. As a technique for forming an oxide film, Patent Document 1 discloses a technique which is used in a vertical processing furnace configured to process a plurality of substrates and includes repeating a step of adsorbing a raw material gas for forming the oxide film onto each of the plurality of substrates, and a step of oxidizing the raw material gas adsorbed onto the substrate by supplying OH radicals to each substrate, wherein the OH radicals are produced by supplying an oxygen gas (O₂ gas) and a hydrogen gas (H₂ gas) into a preliminary chamber and heating these gases.

### PRIOR ART DOCUMENT

### Patent Document

Patent Document 1: International Publication No. WO 2012/066977

### SUMMARY

The present disclosure provides a film-forming method and a film-forming apparatus which are capable of forming an oxide film at high speed, and an oxidation method.

A film-forming method according to an aspect of the present disclosure is a film-forming method of forming an oxide film on a substrate inside a chamber, which includes: adsorbing a raw material gas for forming an oxide film onto the substrate by supplying the raw material gas into the chamber; and oxidizing the raw material gas adsorbed onto the substrate with oxygen-containing radicals produced by supplying a hydrogen gas and an oxygen gas into the chamber while preheating the hydrogen gas and the oxygen gas, wherein the adsorbing the raw material gas and the oxidizing the raw material gas are repeated, and when supplying one or both of the hydrogen gas and the oxygen gas, a supply partial pressure of the one or both of the hydrogen gas and the oxygen gas is changed to be relatively high at an initial supply stage and to gradually decrease over time.

According to the present disclosure, there are provided a film-forming method and a film-forming apparatus which are capable of forming an oxide film at high speed, and an oxidation method.

### BRIEF DESCRIPTION OF DRAWINGS

FIG. 1 is a cross-sectional view illustrating an example of a film-forming apparatus for implementing a film-forming method according to an embodiment.

FIG. 2 is a view illustrating a sequence of the film-forming method according to an embodiment.

FIG. 3A is a schematic view for explaining a film thickness distribution control mechanism in the film-forming method according to an embodiment, which illustrates a case in which a large amount of H₂ gas and O₂ gas are supplied at once to enhance reactivity.

FIG. 3B is a schematic view for explaining the film thickness distribution control mechanism in the film-forming method according to an embodiment, which illustrates a case in which partial pressure(s) of the H₂ gas and/or the O₂ gas is (are) reduced.

FIG. 3C is a schematic view for explaining the film thickness distribution control mechanism in the film-forming method according to an embodiment, which illustrates a case in which a gap between a susceptor and a shower head is narrowed.

FIG. 4 is a view illustrating supply waveforms of the H₂ gas and the O₂ gas per second in Case 1 and Case 2 of Experimental Example 1.

FIG. 5 is a view illustrating a relationship between time and the thickness of a SiO₂ film in Case 1 and Case 2 of Experimental Example 1.

FIG. 6 is a view illustrating a thickness distribution of the SiO₂ film when the gap was changed at each pressure in Experimental Example 2.

FIG. 7 is a view illustrating a gap at each pressure in Experimental Example 2 and an average thickness of the SiO₂ film in a wafer in-plane.

FIG. 8 is a view illustrating a time-dependent change in an amount of OH radicals produced (mole fraction) when a temperature was changed at a pressure of 400 Pa in Experimental Example 3.

FIG. 9 is a view illustrating a time-dependent change in the amount of OH radicals produced (mole fraction) when the temperature was changed at a pressure of 1,200 Pa in Experimental Example 3.

FIG. 10 is a view illustrating a relationship between a temperature of a shower head and a thickness of a SiO₂ film in the presence of a H₂ gas and the absence of the H₂ gas for each susceptor temperature in Experimental Example 4.

### DETAILED DESCRIPTION

Hereinafter, embodiments will be described with reference to the accompanying drawings.

### <Film-Forming Apparatus>

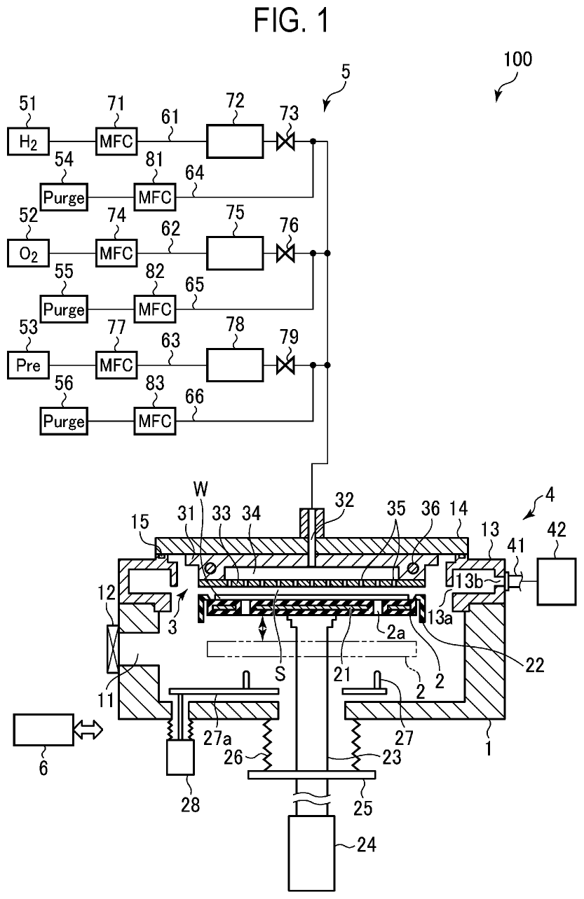

FIG. 1 is a cross-sectional view illustrating an example of a film-forming apparatus for implementing a film-forming method according to an embodiment.

A film-forming apparatus 100 alternately supplies a precursor (a raw material gas) for forming an oxide film and radicals produced by heating a H₂ gas and an O₂ gas to form the oxide film through a typical ALD.

The film-forming apparatus 100 includes a chamber 1, a susceptor 2, a shower head 3, an exhauster 4, a gas supply mechanism 5, and a controller 6.

The chamber 1 is made of a metal such as aluminum, and has a substantially cylindrical shape. A loading/unloading port 11 is formed in the side wall of the chamber 1 to load or unload a wafer W therethrough. The loading/unloading port 11 is configured to be opened or closed by a gate valve 12. An annular exhaust duct 13 having a rectangular cross section is provided on a main body of the chamber 1. The exhaust duct 13 has a slit 13a formed along an inner peripheral surface thereof. In addition, an exhaust port 13b is formed in the outer wall of the exhaust duct 13. A ceiling wall 14 is provided on a top surface of the exhaust duct 13. A space between the ceiling wall 14 and the exhaust duct 13 is hermetically sealed with a seal ring 15.

The susceptor 2 serves to horizontally support thereon a semiconductor wafer (hereinafter, simply referred to as a “wafer”) W, which is a substrate to be processed inside the chamber 1, has a disk shape having a size corresponding to that of the wafer W, and is supported by a support member 23. The susceptor 2 is made of a ceramic material such as aluminum nitride (AlN), and has a heater 21 embedded therein to heat the wafer W. The heater 21 is supplied with power from a heater power supply (not illustrated) to generate heat. By controlling an output of the heater 21 based on a temperature signal of a thermocouple (not illustrated) provided in the vicinity of a wafer placement surface of the top surface of the susceptor 2, the wafer W is controlled to have a predetermined temperature. The temperature of the susceptor 2 is controlled to, for example, 400 degrees C. to 700 degrees C., preferably 400 degrees C. to 640 degrees C.

The susceptor 2 is provided with a cover member 22 made of ceramic such as alumina so as to cover an outer peripheral region of the wafer placement surface and a side surface of the susceptor 2.

The support member 23 configured to support the susceptor 2 extends downward from the center of a bottom surface of the susceptor 2 through a hole formed in a bottom wall of the chamber 1. A lower end of the support member 23 is connected to a lifting mechanism 24. The susceptor 2 is configured to be raised and lowered by the lifting mechanism 24 between a processing position illustrated in FIG. 1 and a transfer position (indicated by a dashed dotted line below the processing position) at which the wafer can be transferred. In addition, a flange 25 is attached to the support member 23 below the chamber 1. A bellows 26 configured to isolate an internal atmosphere of the chamber 1 from ambient air and to be flexible with the vertical movement of the susceptor 2, is provided between the bottom surface of the chamber 1 and the flange 25.

Three wafer support pins 27 (of which only two are illustrated) are provided in the vicinity of the bottom surface of the chamber 1 so as to protrude upward from a lifting plate 27a. The wafer support pins 27 are configured to be raised and lowered by a pin lifting mechanism 28 provided below the chamber 1, via the lifting plate 27a. The wafer support pins 27 are inserted into respective through-holes 2a provided in the susceptor 2 located at the transfer position and are moved upward and downward on the top surface of the susceptor 2. By raising and lowering the wafer support pins 27, the wafer W is delivered between a wafer transfer mechanism (not shown) and the susceptor 2.

The shower head 3 is made of, for example, nickel or a nickel alloy, is provided so as to face the susceptor 2, and functions as a gas introduction member. The shower head 3 includes a disk-shaped main body 31 that is in close contact with the bottom surface of the ceiling wall 14, a gas introduction portion 32 that penetrates the ceiling wall 14 and the main body 31, and a shower plate 33 connected to the underside of the main body 31. A gas diffusion space 34 is formed between the main body 31 and the shower plate 33. A plurality of gas ejection holes 35 are formed in the shower plate 33. A heater 36 is embedded in the main body 31. The heater 36 is supplied with power from a heater power supply (not illustrated) to heat the shower head 3 to a predetermined temperature, for example, 200 degrees C. to 500 degrees C., preferably 400 degrees to 500 degrees C. In the state in which the susceptor 2 is located at the processing position, a processing space S is formed between the shower plate 33 and the susceptor 2.

The exhauster 4 includes an exhaust pipe 41 connected to the exhaust port 13b of the exhaust duct 13, and an exhaust mechanism 42 connected to the exhaust pipe 41 and including a vacuum pump, a pressure control valve (APC), or the like. During the processing, the gas within the chamber 1 reaches the exhaust duct 13 via the slit 13a and is exhausted from the exhaust duct 13 through the exhaust pipe 41 by the exhaust mechanism 42 of the exhauster 4.

The gas supply mechanism 5 includes a H₂ gas source 51 configured to supply a H₂ gas, an O₂ gas source 52 configured to supply an O₂ gas, a raw material gas source 53 configured to supply a film-forming raw material gas (a precursor), and first to third purge gas sources 54 to 56. A first gas supply pipe 61 extends from the H₂ gas source 51, a second gas supply pipe 62 extends from the O₂ gas source 52, and a third gas supply pipe 63 extends from the raw material gas source 53. These pipes are merged with each another and connected to the gas introduction portion 32 of the shower head 3.

The first gas supply pipe 61 is provided with a mass flow controller 71, which is a flow controller, a filling tank (a buffer tank) 72 filled with the H₂ gas, and a high-speed valve 73 in that order from the upstream side. In addition, the second gas supply pipe 62 is provided with a mass flow controller 74, a filling tank 75 filled with the O₂ gas, and a high-speed valve 76 in that order from the upstream side. Further, the third gas supply pipe 63 is provided with a mass flow controller 77, a filling tank 78 filled with the raw material gas, and a high-speed valve 79 in that order from the upstream side.

A first purge gas pipe 64 extends from the first purge gas source 54. An end of the first purge gas pipe 64 is connected to the downstream side of the high-speed valve 73 of the first gas supply pipe 61. A second purge gas pipe 65 extends from the second purge gas source 55. An end of the second purge gas pipe 65 is connected to the downstream side of the high-speed valve 76 of the second gas supply pipe 62. A third purge gas pipe 66 extends from the third purge gas source 56. An end of the third purge gas pipe 66 is connected to the downstream side of the high-speed valve 79 of the third gas supply pipe 63. Mass flow controllers 81, 82, and 83 are provided in the first to third purge gas pipes 64 to 66, respectively.

In addition, opening/closing valves (not illustrated) are provided before and after each of the mass flow controllers 71, 74, 77, 81, 82, and 83.

The raw material gas flows from the raw material gas source 53 through the third gas supply pipe 63, and is filled in the filling tank 78 to have a pressure higher than that in the chamber 1. With this configuration, the raw material gas can be supplied from the filling tank 78 to the shower head 3 at a high pressure. As a result, it is possible to eject a large amount of the raw material gas from gas ejection holes 35 of the shower head 3 into the processing space S at once. The ejected raw material gas is adsorbed onto the surface of the wafer W. As the raw material gas, various gases may be used depending on an oxide film to be formed. For example, in a case of forming a SiO₂ film, a hexachlorodisilane (Si₂Cl₆: HCD) gas, a dichlorosilane (SiH₂Cl₂) gas, or the like may be used. For other oxide films, a titanium tetrachloride (TiCl₄) gas, an aluminum trichloride (AlCl₃) gas, or the like may be used. However, the present disclosure is not limited thereto, and the raw material gas for film formation may be appropriately determined according to an oxide film to be formed.

In addition, the H₂ gas from the H₂ gas source 51 and the O₂ gas from the O₂ gas source 52 pass through the first gas supply pipe 61 and the second gas supply pipe 62, respectively, and are filled in the filling tank 72 and the filling tank 75, respectively, at a pressure higher than that in the chamber 1. As a result, the H₂ gas and the O₂ gas can be supplied from the filling tanks 72 and 75, respectively, to the shower head 3 at a high pressure. Then, the H₂ gas and the O₂ gas are mixed with each other in the gas diffusion space 34 of the shower head 3, and are preheated in the gas diffusion space 34. The preheated H₂ gas and O₂ gas are ejected from the gas ejection holes 35 of the shower head 3 into the processing space S and produce radicals containing oxygen (O), such as O radicals and OH radicals, before reaching the wafer W, thus oxidizing the raw material gas adsorbed onto the surface of the wafer W.

The supply of the raw material gas and the supply of the H₂ gas and the O₂ gas are alternately and intermittently performed by switching the high-speed valves 73, 76, and 79. Typically, an oxide film having a predetermined thickness is formed on the wafer W through ALD.

The purge gases supplied from the first to third purge gas sources 54 to 56 are supplied to the shower head 3 via the first to third purge gas pipes 64 to 66, respectively, and are supplied into the processing gas S from the gas ejection holes 35 of the shower head 3. The purge gas is supplied in a continuous counter-flow manner during film formation, and has a function of purging the residual gas in the processing space S between the supply of the raw material gas and the supply of the H₂ gas and the O₂ gas. As the purge gas, an inert gas (e.g., a noble gas such as an Ar gas, or a N₂ gas) may be used.

The controller 6 controls respective components, specifically, the mass flow controllers 71, 74, 77, 81, 82, and 83, the high-speed valves 73, 76, and 79, the power supply for the heaters 21 and 36, the lifting mechanism 24, the pin lifting mechanism 28, the exhaust mechanism 42, and the like. The controller 6 includes a CPU (computer), and includes a main controller configured to control the respective components, an input device, an output device, a display device, and a storage device. The storage device stores parameters of processes executed by the film-forming apparatus 100. In addition, the storage device includes a storage medium which stores programs for controlling processes to be executed by the film-forming apparatus 100, that is, processing recipes. The main controller calls a predetermined processing recipe stored in the storage medium, and controls the film-forming apparatus 100 to perform a predetermined process based on the processing recipe.

### <Film-Forming Method>

Next, a film-forming method according to an embodiment, which uses the film-forming apparatus 100 configured as above, will be described.

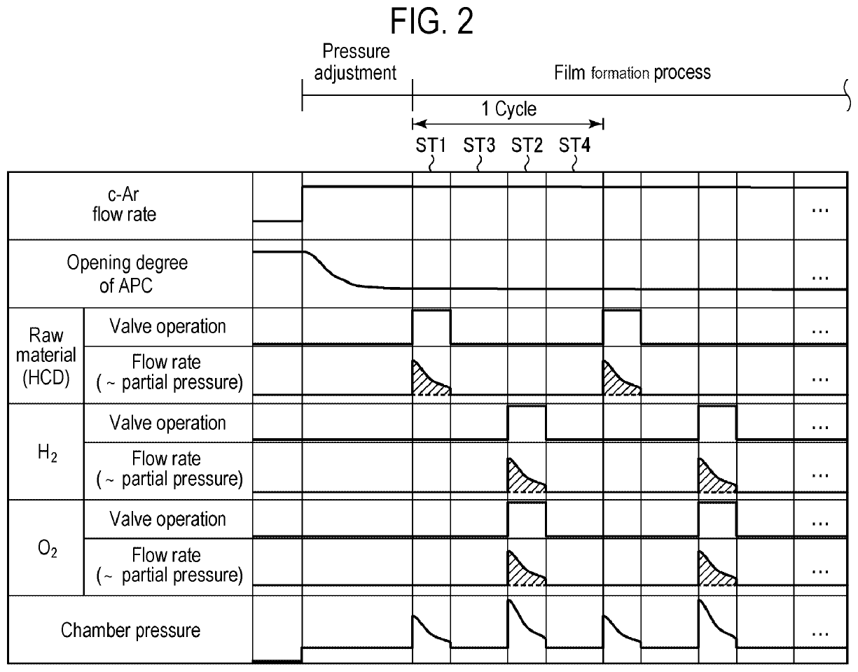

FIG. 2 is a view illustrating a sequence of the film-forming method according to an embodiment. In the present embodiment, a gap between the susceptor 2 and the shower head 3 is set to 7 to 80 mm, a temperature of the susceptor 2 is set to preferably 400 to 700 degrees C., more preferably 400 to 640 degrees C., a temperature of the shower head 3 is set to 200 to 500 degrees, more preferably 400 to 500 degrees C., and an internal pressure of the chamber 1 is adjusted by the APC of the exhaust mechanism 42 while supplying the inert gas serving as a purge gas (e.g., Ar gas) from the first to third purge gas sources 54 to 56 at a predetermined flow rate. Then, a film formation process is executed in a state in which an opening degree of the APC is fixed to a value at the time of adjustment of the internal pressure. The film formation process includes performing a step ST1 of supplying the raw material gas (e.g., a, HCD gas) (ST1) and a step ST2 of supplying the H₂ gas and the O₂ gas in an alternate and intermittent manner to form an oxide film having a predetermined thickness on the surface of the wafer W through the typical ALD. At this time, the purge gas is supplied in a continuous counter-flow manner during the film formation. After steps ST1 and ST2, purge steps ST3 and ST4 of purging the residual gas in the processing space S are performed. In addition, either the H₂ gas or the O₂ gas may be caused to continuously flow as long as it does not react with the raw material gas.

In step ST2, the H₂ gas and the O₂ gas are mixed with each other and preheated in the gas diffusion space 34 of the shower head 3. The preheated H₂ gas and O₂ gas are ejected from the gas ejection holes 35 of the shower head 3 into the processing space S, and produce radicals containing oxygen (O), such as O radicals and OH radicals, before reaching the wafer W, thus oxidizing the raw material gas adsorbed onto the surface of the wafer W. By performing oxidation using radicals in this way, it is possible to increase oxidization power compared with, for example, the case of supplying the O₂ gas alone. At this time, a ratio (partial pressure ratio) of the H₂ gas to the H₂ gas+the O₂ gas in flow rate may be preferably 10 to 50% by volume.

Further, in ST2, when the H₂ gas and the O₂ gas are supplied, the partial pressures thereof are changed. Specifically, the partial pressures of the supplied H₂ gas and O₂ gas are changed to be relatively high at the initial supply stage and to gradually decrease over time. Such a change in supply partial pressures may be implemented by filling the filling tanks 72 and 75 with the H₂ gas and the O₂ gas, respectively, to have pressures higher than that in the chamber 1 and opening the high-speed valves 73 and 76 to supply these gases from the respective filling tanks 72 and 75 (filling-flow). As described above, by increasing the partial pressures of the H₂ gas and the O₂ gas at the initial supply stage, in addition to using radicals produced by heating the H₂ gas and the O₂ gas during the oxidation process, it is possible to further enhance the oxidization power.

That is, by increasing the supply partial pressures of the H₂ gas and the O₂ gas at the initial stage of film formation, it is possible to oxidize the raw material gas adsorbed onto the wafer W at once. This makes it possible to significantly enhance the oxidization power compared to the case in which the raw material gas is supplied at a normal constant partial pressure. Therefore, it is possible to significantly shorten the time required for film formation sequence. As described above, it is possible to reduce the amounts of supplied H₂ gas and O₂ gas by increasing the supply partial pressures at the initial stage of film formation and then decreasing the supply partial pressures.

In some embodiments, a filling tank may be provided in only one of the pipe for supplying the H₂ gas and the pipe for supplying the O₂ gas so that the above-mentioned change in supply partial pressure is generated in only one of the H₂ gas and the O₂ gas.

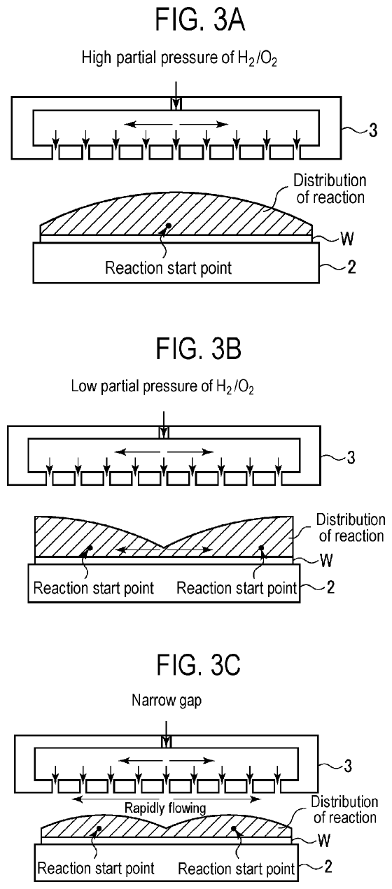

By changing the supply partial pressures of the H₂ gas and the O₂ gas in this way, it is also possible to control the distribution of the film thickness without significantly changing the oxidation amount (average film thickness). For example, it is possible to control the film thickness distribution of the oxide film based on the gap between the shower head and the susceptor, the pressure, the partial pressures of the H₂ gas and the O₂ gas, and the like. A mechanism for controlling such a film thickness distribution will be described with reference to FIGS. 3A to 3C.

In the case of oxidation using radicals, it is known that a traveling distance from the introduction of radicals to the reaction thereof is required. However, in the case in which the H₂ gas and the O₂ gas are supplied, for example, in a filling-flow manner, and the supply partial pressures of the H₂ gas and the O₂ gas are changed to be relatively high at the initial supply stage and to gradually decrease over time, it is possible to enhance reactivity by supplying these gases in large amounts at once at the initial supply stage. Therefore, as illustrated in FIG. 3A, at the initial supply stage, the H₂ gas and the O₂ gas ejected from the shower head 3 immediately react in the central portion near the gas supply portion in which reactivity is high to produce radicals. In this case, the H₂ gas and the O₂ gas are consumed in the center of the wafer W and thus the amounts of H₂ gas and O₂ gas are insufficient in the peripheral portion of the wafer W. Accordingly, it is presumed that a film formation distribution in which the thickness is large at the center and small at the peripheral portion may be formed.

Meanwhile, in the gas supply that causes such a partial pressure change, for example, in the filling flow, when the partial pressure of the H₂ gas and/or the partial pressure of the O₂ gas are reduced by increasing the counter-flow in which the flow rate of the H₂ gas and/or the flow rate of the O₂ gas are decreased and the full pressure is lowered, the time taken until the reaction starts is delayed. In that case, it is presumed that the start point of the radical production reaction moves to the peripheral portion of the wafer W so that the film thickness at the peripheral portion of the wafer W may be increased without significantly changing the oxidation amount (the average film thickness), as illustrated in FIG. 3B.

In addition, when the gap between the susceptor 2 and the shower head 3 is narrowed, as illustrated in FIG. 3C, flow velocities of the H₂ gas and the O₂ gas ejected from the shower head 3 are increased so that the start point of the radical production reaction is likely to move to the peripheral portion of the wafer W. Therefore, it is presumed that, by narrowing the gap between the susceptor 2 and the shower head 3, it is possible to increase the film thickness at the peripheral portion of the wafer W without significantly changing the oxidation amount (the average film thickness).

When the H₂ gas and the O₂ gas are supplied at a normal constant partial pressure, the concentrations of the H₂ gas and the O₂ gas inside the shower head 3 are averaged. This makes it difficult to perform the film thickness distribution control.

The pressures of the filling tanks 72 and 75 may be preferably about 2 to 100 times the internal pressure of the chamber 1. In addition, in the partial pressure distribution when the filling tanks are used, the partial pressure at the time of stopping the supply of the gases may be preferably 40 to 70% of a partial pressure at the peak time at the initial supply stage. As a result, it is possible to effectively exhibit the above effects.

In the present embodiment, the supply partial pressure of the raw material gas may be changed even when the raw material gas is supplied. That is, it is possible to change the supply partial pressure of the raw material gas to be relatively high at the initial supply stage and to gradually decrease over time. Specifically, the change in partial pressure is achieved by filling the filling tank 78 with the raw material gas to have a pressure higher than the internal pressure of the chamber 1 and opening the high-speed valve 79 to supply the raw material gas from the filling tank 78. By increasing the partial pressure at the initial stage of supplying the raw material gas in this way, it is possible to cause the raw material gas to be supplied and adsorbed in a short period of time. This makes it possible to further shorten the time taken to perform the film formation sequence. In addition, by supplying the raw material gas with the change in partial pressure, it is possible to perform the film thickness distribution control without greatly changing the average film thickness itself, as in the case of the H₂ gas and the O₂ gas. The pressure of the filling tank 78 for implementing the change in supply partial pressure may also be preferably about 2 to 100 times the internal pressure of the chamber 1. In addition, in the partial pressure distribution of the raw material gas, the partial pressure at the time of stopping the supply of the gases may be preferably 80 to 90% of the partial pressure at the peak time at the initial supply stage.

In the present embodiment, preferable ranges of the film formation conditions when the diameter of the wafer W is 300 mm are as follows.
Gap between susceptor 2 and shower head 3: 7 to 80 mm
Time of ST1: 0.05 to 0.1 seconds
Time of ST2: 0.1 to 2 seconds (more preferably 0.5 to 1.5 seconds)
Times of ST3 and ST4: 0.2 to 2 seconds
Internal pressure of chamber 1 (processing space S): 350 to 1,600 Pa
Flow rate of H₂ gas: 200 to 1,500 sccm
Flow rate of O₂ gas: 200 to 4,500 sccm
Counter-flow (purge gas): 500 to 9,000 sccm in total for all lines
Temperature of shower head: 200 to 500 degrees C. (more preferably 400 to 500 degrees C.)
Temperature of susceptor: 400 to 700 degrees C. (more preferably 400 to 640 degrees C.)

Since the pressure changes as illustrated in FIG. 2 when the filling tank is used, the pressure when the filling tank is used is defined as a chamber peak pressure (value indicated on the capacitance manometer). In addition, the amounts of ejected H₂ gas and O₂ gas per cycle when the filling tank is used correspond to the areas of portions indicated by hatching in FIG. 2, and may be preferably 20 to 120 scc/cycle (where the unit “scc” indicates the volume of gas at 0 degrees C. and 1 atm). Furthermore, the flow rate of the raw material gas may be appropriately set according to the type of oxide film to be formed, the raw material, or the like.

As described above, in the vertical processing furnace for processing the plurality of substrates, which is disclosed in Patent Document 1, the oxide film is formed by repeating the step of adsorbing the raw material gas onto each substrate and the step of oxidizing the raw material gas adsorbed onto each substrate by supplying, to each substrate, radicals produced by heating the O₂ gas and the H₂ gas in the preliminary chamber. This makes it possible to form the oxide film at a high film formation rate of a certain level. In recent years, a demand has existed to form an oxide film at a higher film formation rate using a single-wafer-type apparatus.

Meanwhile, in the present embodiment, one or both of the H₂ gas and the O₂ gas are supplied with the partial pressures thereof changed. Specifically, the supply partial pressures of the H₂ gas and the O₂ gas are changed to be relatively high at the initial supply stage and to gradually decrease over time. By increasing the supply partial pressures at the initial stage of film formation during the oxidation process in this way, it is possible to significantly increase oxidization power through the use of radicals produced by heating the H₂ gas and the O₂ gas. This makes it possible to significantly shorten the time required for the film formation sequence.

In the present embodiment, it is possible to effectively carry out the operation of increasing the supply partial pressures at the initial stage of film formation by filling the respective filling tanks 72 and 75 with the H₂ gas and the O₂ gas so as to have pressures higher than the internal pressure of the chamber 1, and supplying the H₂ gas and the O₂ gas into the processing space S from the respective filling tanks 72 and 75 via the shower head 3.

In addition, in a gas supply method in which the supply partial pressure in the film formation process has a change in supply partial pressure of a relatively high level, specifically, a gas supply method using the filling tank, it is possible to control the thickness distribution of the oxide film by adjusting parameters, such as the distance between the susceptor and the shower head, the pressure, the partial pressure of gas, and the like.

The method of increasing reactivity based on a change in partial pressure is not limited to the formation of the oxide film, but may be effectively applied to the formation of other films. For example, even in a case in which a metal raw material gas such as a TiCl₄ gas, a WCl₆ gas or the like is caused to react with a reaction gas such as a NH₃ gas, a H₂ gas or the like, to form a metal film, it is possible to enhance reactivity by a change in partial pressure.

### <Other Applications>

Although embodiments has been described above, it should be noted that the embodiments disclosed herein are exemplary in all respects and are not restrictive. The above-described embodiments may be omitted, replaced or modified in various forms without departing from the scope and spirit of the appended claims.

For example, in the embodiments described above, the case in which the SiO₂ film is used as the oxide film and the HCD gas is used as the raw material gas has been illustrated as an example, but the present disclosure is not limited thereto. As described above, various raw material gases may be used to form various oxide films.

In addition, the film-forming apparatus illustrated in FIG. 1 is merely an example, and any apparatus may be adopted as long as it has a mechanism for preheating and ejecting the H₂ gas and the O₂ gas.

In addition, in the embodiments described above, the supply partial pressures of gases have been described to be changed using the respective filling tanks, but the present disclosure is not limited thereto, and any manner may be employed as long as the change in partial pressure described above can be achieved.

In addition, in the embodiments described above, the example in which the oxide film is formed through ALD by repeating the supply of the raw material gas and the oxidation process has been illustrated, but the present disclosure is not limited to ALD in a strict sense.

In addition, in the embodiments described above, the example in which the oxide film is formed by repeating the step of adsorbing the raw material gas and the step of oxidizing the raw material gas using radicals containing oxygen has been illustrated, but the oxide film may be formed by oxidizing the surface of the substrate. In this case, by repeating oxidizing and purging, it is possible to obtain the same effects as those in the above-described embodiment in which the step of adsorbing the raw material gas and the step of oxidizing the raw material gas are repeated. That is, through the oxidizing, the effect of increasing the oxidization power by changing the supply partial pressure of gas to be relatively high at the initial supply stage and to gradually decrease over time and the effect of controlling the thickness distribution of the oxide film by adjusting parameters are obtained. In addition, it is possible to adjust the thickness distribution of the oxide film by repeating the oxidizing and purging described above after the oxide film is formed.

Furthermore, in the embodiments described above, the semiconductor wafer has been described as an example of the substrate to be processed, but the present disclosure is not limited to the semiconductor wafer, and may use another substrate, such as a glass substrate used for a flat panel display (FPD), a ceramic substrate, or the like.

### EXPERIMENTAL EXAMPLES

Next, experimental examples will be described.

### Experimental Example 1

In Experimental Example 1, in order to simulate the process of supplying the H₂ gas and the O₂ gas after the supply of the raw material gas, the H₂ gas and the O₂ gas were used as oxidizing agents, and the silicon substrate from which the natural oxide film was removed with hydrofluoric acid was oxidized. In Case 1, the SiO₂ film was formed as an oxide film by supplying both the H₂ gas and the O₂ gas at a constant flow rate without using the respective filling tanks, and in Case 2, the SiO₂ film was formed as an oxide film by supplying the H₂ gas at a constant flow rate and supplying the O₂ gas in a filling-flow manner using the filling tank. The conditions used as common conditions at this time were set as follows: temperature of susceptor: 640 degrees C., pressure: 1,200 Pa, and gap between susceptor 2 and shower head 3: 20 mm.

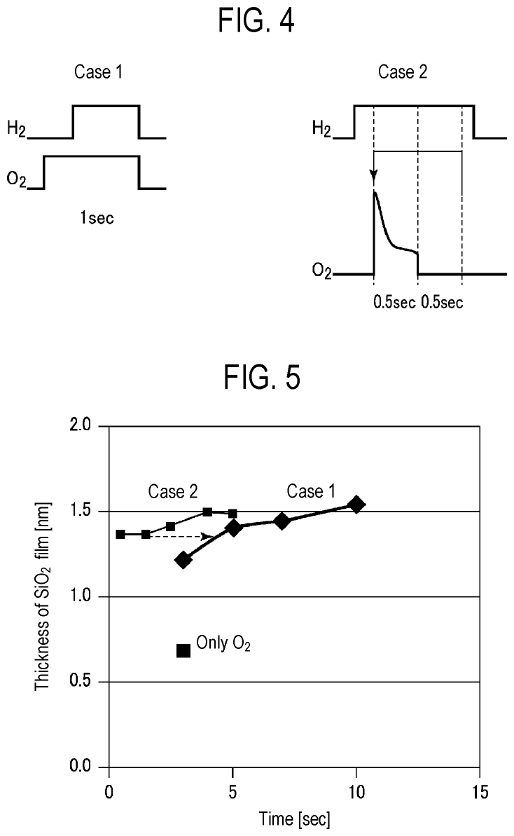

The supply waveforms of the H₂ gas and the O₂ gas per second in Case 1 and Case 2 are illustrated in FIG. 4. In Case 1, the flow rate of H₂ gas/O₂ gas was set to 1,375/4,125 sccm, and H₂ gas/O₂ gas was set to 23/69 scc/cycle in terms of one second/cycle. In Case 2, the flow rate of H₂ gas/O₂ gas was set to 200/450 sccm, and H₂ gas/O₂ gas was set to 6.6/15 scc/cycle in terms of one second/cycle. In addition, during the time period of 0.5 seconds in the initial supply stage, the full amount of 02 gas was supplied in the filling-flow manner.

The relationship between time and thickness of the SiO₂ film in each of Case 1 and Case 2 is illustrated in FIG. 5. As illustrated in FIG. 5, in Case 2 in which the O₂ gas was supplied in the filling-flow manner, it took 0.5 seconds to obtain the thickness of the SiO₂ film, but took 4 seconds in Case 1. Thus, it can be seen that the filling-flow manner provides eight times of oxidization power compared with an auto-flow manner. It can also be seen that the filling-flow manner is capable of significantly reducing gas consumption. Although this experiment does not include the step of adsorbing the raw material gas, it is presumed that the same result would be obtained even when the step of adsorbing the raw material gas is included.

### Experimental Example 2

In Experimental Example 2, the H₂ gas and the O₂ gas were used as oxidizing agents, and the gap (7 to 50 mm) between the susceptor and the shower head and the pressure (400 to 1,200 Pa) were changed to oxidize the silicon substrate from which the natural oxide film was removed. At this time, the oxide film was formed by repeating, for 5 cycles, the step ST2 of supplying the H₂ gas and the O₂ gas and the step ST4 of purging the residual gas, which were described above. The film formation conditions were set as follows: temperature of susceptor: 640 degrees C., ST2: 1 second, ST4: 2.4 seconds, and the amount of supplied H₂ gas and O₂ gas: 21.3 scc/cycle.

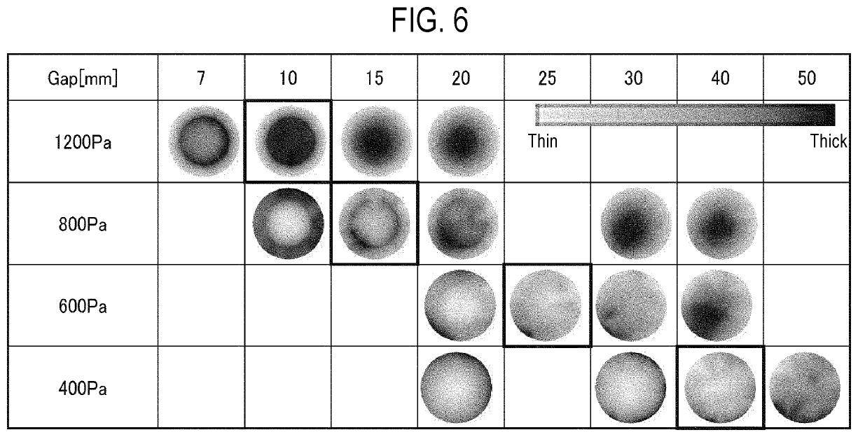

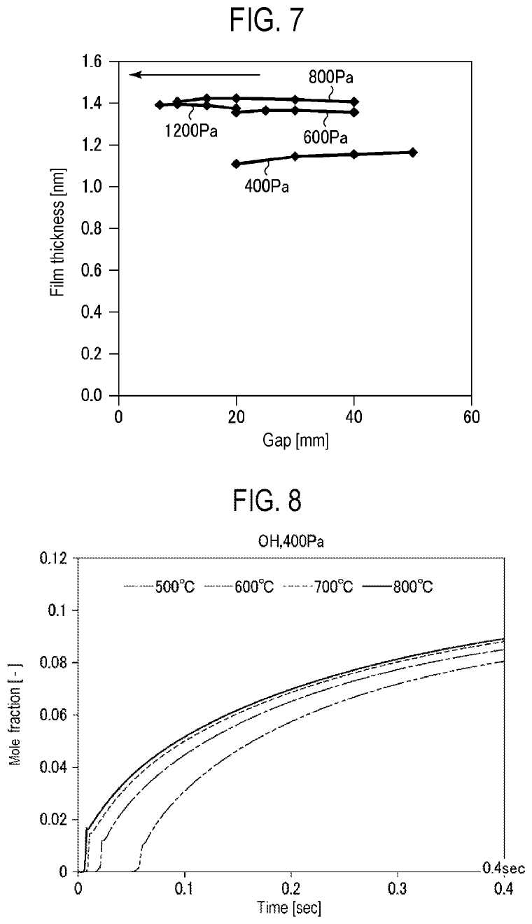

FIG. 6 is a view illustrating the thickness distribution of the SiO₂ film when the gap was changed at each pressure. In addition, FIG. 7 is a view illustrating the relationship between the gap at each pressure and the average thickness of the SiO₂ film. As illustrated in FIG. 6, it can be seen that it is possible to adjust the thickness distribution of the SiO₂ film on the wafer W from the center thickness to the edge thickness by adjusting the gap at each pressure. At the same pressure, the oxidation amount (the average thickness of the SiO₂ film) is substantially the same even if the gaps are different. Although this experiment does not include the step of adsorbing the raw material gas, it is presumed that the same result would be obtained even when the step of adsorbing the raw material gas is included.

### Experimental Example 3

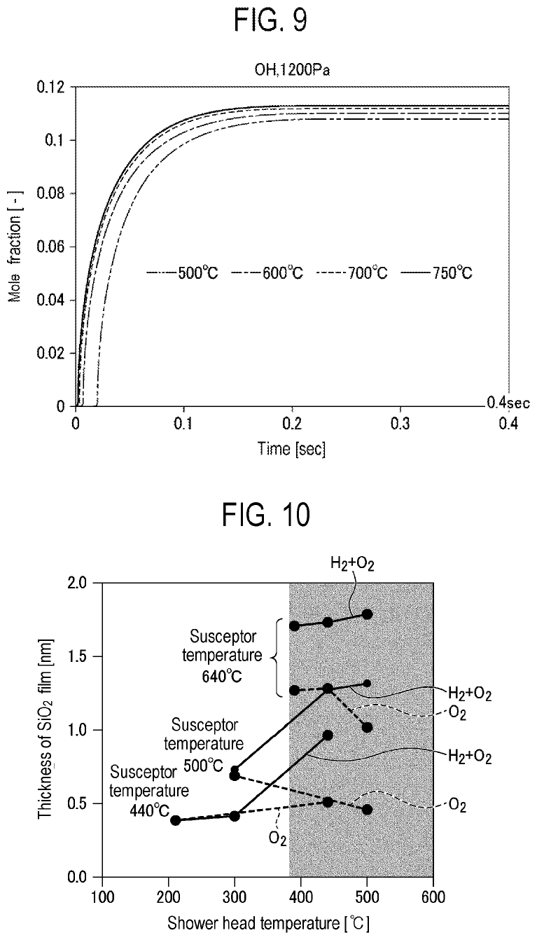

In Experimental Example 3, the amount of OH radicals (mole fraction) that were produced when the temperatures were set to 500 degrees C., 600 degrees C., 700 degrees C., and 800 degrees C., and the pressures were set to 400 Pa and 1,200 Pa, was calculated. FIGS. 8 and 9 are views illustrating a time-dependent change in the amount of produced OH radicals (mole fraction) at each temperature when the pressures were set to 400 Pa and 1,200 Pa, respectively.

From FIGS. 8 and 9, it can be seen that the higher the temperature and the higher the pressure, the faster the start of OH production. This means that in the case of the filling-flow manner, depending on the temperature and pressure (partial pressure), the OH production reaction start position changes, that is, the OH distribution changes. That is, focusing on the pressure, it is understood that the OH production reaction starts at a place near the gas supply port (the center of the shower head) at a high pressure and starts at a place far from the supply port at a low pressure.

### Experimental Example 4

In Experimental Example 4, the temperature of the stage and the temperature of the shower head were changed, and the O₂ gas or the H₂ gas+the O₂ gas was supplied as an oxidizing agent to perform oxidation. The conditions used at this time were set as follows: gap: 20 mm, pressure: 1,200 Pa, flow rate of H₂ gas: 1,375 sccm, flow rate of 02 gas: 4,125 sccm, flow rate of counter-flow: 495 sccm, and time: 10 seconds.

FIG. 10 is a view illustrating the relationship between the temperature of the shower head and the thickness of the SiO₂ film in the oxidation process with and without the H₂ gas for each temperature of the susceptor. As illustrated in FIG. 10, in the case of the H₂ gas+the O₂ gas, the thickness of the SiO₂ film was observed when the temperature of the susceptor was 400 degrees C. or higher and the temperature of the shower head was 400 degrees C. or higher. However, in the case of the O₂ gas alone, an increase in the film thickness due to the increase in the temperature of the shower head was not observed, and a decrease in the film thickness was observed with the increase in the temperature of the shower head when the temperature of the susceptor was 500 degrees C. or higher. From this, it was confirmed that it is possible to obtain the effect of increasing the oxidization power through the production of radicals by supplying the H₂ gas and the O₂ gas and heating the shower head to 400 degrees C. or higher. Although this experiment did not cause a change in partial pressure using a filling tank, it is presumed that the same result would be obtained even when the change in partial pressure is caused.

### EXPLANATION OF REFERENCE NUMERALS

1: chamber, 2: susceptor, 3: shower head, 4: exhauster, 5: gas supply mechanism, 6: controller, 51: H₂ gas source, 52: O₂ gas source, 53; raw material gas source, 72, 75, 78: filling tank, 73, 76, 79: high-speed valve, S: processing space, W: semiconductor wafer (substrate)

1. A film-forming method of forming an oxide film on a substrate inside a chamber, the film-forming method comprising:
adsorbing a raw material gas for forming the oxide film onto the substrate by supplying the raw material gas into the chamber; and
oxidizing the raw material gas adsorbed onto the substrate with oxygen-containing radicals produced by supplying a hydrogen gas and an oxygen gas into the chamber while preheating the hydrogen gas and the oxygen gas,
wherein the adsorbing the raw material gas and the oxidizing the raw material gas are repeated, and
when supplying at least one of the hydrogen gas and the oxygen gas, a supply partial pressure of the at least one of the hydrogen gas and the oxygen gas is changed to be relatively high at an initial supply stage and to gradually decrease over time.

2. The film-forming method of claim 1, wherein the supply partial pressure of the at least one of the hydrogen gas and the oxygen gas is changed by filling a filling tank, which is provided in a gas supply pipe configured to change the supply partial pressure, with the at least one of the hydrogen gas and the oxygen gas at a pressure higher than an internal pressure of the chamber, and opening a valve provided at a downstream side of the filling tank in a gas supply path to supply the at least one of the hydrogen gas and the oxygen gas from the filling tank.

3. The film-forming method of claim 1, wherein the substrate is heated to a temperature of 400 to 700 degrees C.

4. The film-forming method of claim 1, wherein the hydrogen gas and the oxygen gas are preheated to a temperature of 200 to 500 degrees C.

5. The film-forming method of claim 4, wherein the hydrogen gas and the oxygen gas are preheated to a temperature of 400 to 500 degrees C.

6. The film-forming method of claim 1, wherein the hydrogen gas and the oxygen gas are supplied into the chamber via a shower head, and preheated inside the shower head.

7. The film-forming method of claim 1, wherein in the adsorbing the raw material gas, a supply partial pressure of the raw material gas is changed to be relatively high at an initial supply stage and to gradually decrease over time.

8. The film-forming method of claim 7, wherein the supply partial pressure of the raw material gas is changed by filling a filling tank, which is provided in a raw material gas supply pipe, with the raw material gas at a pressure higher than an internal pressure of the chamber, and opening a valve provided at a downstream side of the filling tank in a gas supply path to supply the raw material gas from the filling tank.

9. The film-forming method of claim 1, further comprising: continuously supplying an inert gas into the chamber in a counter-flow manner during a film formation process; and
purging an interior of the chamber with the inert gas, the purging being performed after the adsorbing the raw material gas and the oxidizing the raw material gas.

10. A film-forming apparatus for forming an oxide film on a substrate, comprising:
a chamber in which the substrate is accommodated;
a stage provided inside the chamber and configured to place the substrate thereon;
a first heater configured to heat the substrate placed on the stage;
a gas supplier configured to supply a raw material gas for forming the oxide film on the substrate, a hydrogen gas, and an oxygen gas;
an exhauster configured to exhaust an inside of a chamber;
a second heater configured to preheat at least the hydrogen gas and the oxygen gas; and
a controller configured to control the first heater, the second heater, the gas supplier, and the exhauster,
wherein the gas supplier includes at least one filling tank provided in at least one pipe configured to supply the hydrogen gas and the oxygen gas therethrough and in which the hydrogen gas and the oxygen gas are filled, and a valve provided at a downstream side of the filling tank in a gas supply path,
wherein the controller controls the gas supplier and the second heater to:
repeat adsorbing the raw material gas onto the substrate by supplying the raw material gas into the chamber and oxidizing the raw material gas adsorbed onto the substrate with oxygen-containing radicals produced by supplying the hydrogen gas and the oxygen gas into the chamber while preheating the hydrogen gas and the oxygen gas by the second heater; and
when supplying at least one of the hydrogen gas and the oxygen gas, supply the at least one of the hydrogen gas and the oxygen gas from the filling tank such that a supply partial pressure is relatively high at an initial supply stage and gradually decreases over time by filling the filling tank with the at least one of the hydrogen gas and the oxygen gas at a pressure higher than an internal pressure of the chamber and opening the valve.

11. The film-forming apparatus of claim 10, wherein the first heater is configured to heat the substrate to a temperature of 400 to 700 degrees C.

12. The film-forming apparatus of claim 10, wherein the second heater is configured to preheat the hydrogen gas and the oxygen gas to a temperature of 200 to 500 degrees C.

13. The film-forming apparatus of claim 12, wherein the second heater is configured to preheat the hydrogen gas and the oxygen gas to a temperature of 400 to 500 degrees C.

14. The film-forming apparatus of claim 10, further comprising:
a shower head to which at least the hydrogen gas and the oxygen gas are supplied from the gas supplier, and configured to temporarily store the hydrogen gas and the oxygen gas supplied thereto and subsequently, to introduce the hydrogen gas and the oxygen gas into the chamber,
wherein the second heater preheats the hydrogen gas and the oxygen gas supplied into the shower head.

15. The film-forming apparatus of claim 10, wherein the gas supplier includes a filling tank provided in a pipe through which the raw material gas is supplied and configured to be filled with the raw material gas, and a valve provided at a downstream side of the filling tank in a gas supply path, and
when supplying the raw material gas, the controller controls the filling tank to supply the raw material gas such that a supply partial pressure is relatively high at an initial supply stage and gradually decreases over time by filling the filling tank with the raw material gas at a pressure higher than an internal pressure of the chamber and opening the valve.

16. The film-forming apparatus of claim 10, wherein the gas supplier is configured to supply an inert gas into the chamber,
the controller controls the gas supplier to continuously supply the inert gas into the chamber in a counter-flow manner during a film formation process, and
after the raw material gas is adsorbed onto the substrate and after the hydrogen gas and the oxygen gas are supplied into the chamber, an interior of the chamber is purged by the inert gas.

17. A method of performing an oxidation process on a substrate inside a chamber, the method comprising:
supplying a hydrogen gas and an oxygen gas into the chamber while preheating the hydrogen gas and the oxygen gas; and
oxidizing a surface of the substrate with oxygen-containing radicals produced by the preheated hydrogen gas and the preheated oxygen gas,
wherein, when supplying at least one of the hydrogen gas and the oxygen gas, a supply partial pressure of the at least one of the hydrogen gas and the oxygen gas is changed to be relatively high at an initial supply stage and gradually decrease over time.

18. The method of claim 17, wherein the supply partial pressure of the at least one of the hydrogen gas and the oxygen gas is changed by filling a filling tank, which is provided in a gas supply pipe through which the at least one of the hydrogen gas and the oxygen gas flows, with the at least one of the hydrogen gas and the oxygen gas at a pressure higher than an internal pressure of the chamber and opening a valve provided at a downstream side of the filling tank in a gas supply path to supply the at least one of the hydrogen gas and the oxygen gas from the filling tank.

19. The method of claim 17, wherein the hydrogen gas and the oxygen gas are preheated to a temperature of 400 to 500 degrees C.

20. The method of claim 17, wherein the hydrogen gas and the oxygen gas are supplied into the chamber via a shower head and preheated inside the shower head.
